(19) United States
(12) Patent Application Publication
(10) Pub. No.: US 2011/0121765 A1
(43) Pub. Date: May 26, 2011

(54) Driver for piezoelectric actuator

(75) Inventors: Douglas James Anderson, Queen Creek, AZ (US); Harold Gee Yee, Chandler, AZ (US)

(73) Assignee: World Properties, Inc., Lincolnwood, IL (US)

(21) Appl. No.: 12/592,353

(22) Filed: Nov. 24, 2009

(51) Int. Cl. H01L 41/04; H03B 1/00

(52) U.S. Cl. 318/116; 327/108

(57) ABSTRACT

A driver for a piezoelectric actuator includes a pulse width modulator and an output amplifier packaged as a single semiconductor device, preferably on a single semiconductor die. The driver includes a first boost converter that supplies power to the output amplifier, which preferably has programmable gain. A second amplifier, for driving the gate of a switching transistor in the first boost converter, is powered by a second boost converter. The piezoelectric actuator provides tactile feedback for the keyboard or the display in a battery operated electronic device.

### BACKGROUND

This invention relates to a battery powered driver and, in particular, to a single chip driver for a piezoelectric actuator.

A piezoelectric actuator requires high voltage, greater than typical battery voltages of 1.5 to 12.6 volts. A “high” voltage is 20-200 volts, with 100-120 volts currently being a typical drive voltage. Some line driven power supplies for actuators provide as much as 1000 volts. Producing high voltage from a battery is more difficult than producing high voltage from a power line. As noted in U.S. Pat. No. 7,468,573 (Dai et al.), the high voltage required “to drive piezoelectric actuators in today's small electronic devices is undesirable.” The solution proposed in the '573 patent is to use two pulses of “lower” voltage instead of a single pulse at high voltage. The “lower” voltage is not disclosed. Single layer actuators generally require a higher voltage than multilayer actuators. Multilayer actuators have the advantage of providing greater feedback force than single layer actuators.

A voltage boost circuit can be used to convert the low voltage from a battery to a higher voltage for the driver. In a boost converter, the energy stored in an inductor is supplied to a capacitor as pulses of current at high voltage.

FIG. 1 is a schematic of a circuit including a known boost converter; e.g. see U.S. Pat. No. 3,913,000 (Cardwell, Jr.) or U.S. Pat. No. 4,527,096 (Kindlmann). Inductor 11 and transistor 12 are connected in series between supply 13 and ground. When transistor 12 turns on (conducts), current flows through inductor 11, storing energy in the magnetic field generated by the inductor. Current through inductor 11 increases quickly, depending upon battery voltage, inductance, internal resistances, and the on-resistance of transistor 12. When transistor 12 shuts off, the magnetic field collapses at a rate determined by the turn-off characteristic of transistor 12. The rate of collapse is quite rapid, much more rapid than the rate at which the field increases. The voltage across inductor 11 is proportional to the rate at which the field collapses. Voltages of one hundred volts or more are possible. Thus, a low voltage is converted into a high voltage by the boost converter.

When transistor 12 shuts off, the voltage at junction 15 is substantially higher than the voltage on capacitor 14 and current flows through diode 16, which is forward biased. Each pulse of current charges capacitor 14 a little and the charge on the capacitor increases incrementally. At some point, the voltage on capacitor 14 will be greater than the supply voltage. Diode 16 prevents current from flowing to supply 13 from capacitor 14. The voltage on capacitor 14 is the supply voltage for other components, such as amplifier 21.

As used herein, “supply” provides the operating power for a circuit, as opposed to “bias” that provides control or offset. For example, it is known in the memory art to provide a boost circuit for biasing the gate of a field effect transistor; U.S. Pat. No. 4,660,177 (O'Conner).

The output of amplifier 21 is coupled to piezoelectric actuator 22. The input to amplifier 21 can receive an alternating current signal, for bidirectional movement, or a direct current signal, for unidirectional movement or as half of a complementary drive (two amplifiers, one for each polarity, coupled to opposite terminals of piezoelectric actuator 22). In a complementary drive, the absolute magnitudes of the boosted voltages are greater than the absolute magnitude of the battery voltage. A complementary drive can use half the high voltage (or be provided with twice the high voltage) of a single drive but requires two boost converters.

In FIG. 1, the gate drive for transistor 12, illustrated as pulse width modulator 24, transistor 12, and amplifier 21 are separate semiconductor devices. Diode 16 is often on the same die as switching transistor 12. This construction is necessarily large and expensive.

Thus, there is a need for a battery powered driver that is a single chip power supply for piezoelectric actuators. Although die size is increased and the die is more expensive, the total cost for semiconductors can be reduced. There is also a problem of combining devices without reducing efficiency. An external supply voltage of three volts (two batteries), typical for today's portable electronics, restricts circuit design and reduces efficiency.

In view of the foregoing, it is therefore an object of the invention to provide a single chip driver for a piezoelectric actuator that is as efficient as battery powered drivers using several semiconductor devices.

Another object of the invention is to reduce the component count in drivers for piezoelectric actuators.

A further object of the invention is to improve the efficiency of a driver powered by a low voltage external supply.

### SUMMARY OF THE INVENTION

The foregoing objects are achieved in the invention in which a driver for a piezoelectric actuator includes a pulse width modulator and an output amplifier packaged as a single semiconductor device, preferably on a single semiconductor die. The driver includes a first boost converter that supplies power to the output amplifier, which preferably has programmable gain. A second amplifier, for driving the gate of a switching transistor in the first boost converter, is powered by a second boost converter.

### BRIEF DESCRIPTION OF THE DRAWINGS

A more complete understanding of the invention can be obtained by considering the following detailed description in conjunction with the accompanying drawings, in which:

FIG. 1 is a schematic of a driver, constructed in accordance with the prior art, coupled to a piezoelectric actuator;

FIG. 2 is a perspective view of an electronic device having a display and a keypad, either or both of which include a piezoelectric actuator;

FIG. 3 is a schematic of a driver, constructed in accordance with the invention, coupled to a piezoelectric actuator;

FIG. 4 is a more detailed schematic of a driver, constructed in accordance with a preferred embodiment of the invention, coupled to a piezoelectric actuator;

FIG. 5 is a schematic of a driver, constructed in accordance with an alternative embodiment the invention, coupled to a piezoelectric actuator;

FIG. 6 is a schematic of a driver having complementary outputs, constructed in accordance with an alternative embodiment the invention and coupled to a piezoelectric actuator; and

FIG. 7 is a schematic of a driver having complementary outputs and a single voltage supply.

### DETAILED DESCRIPTION OF THE INVENTION

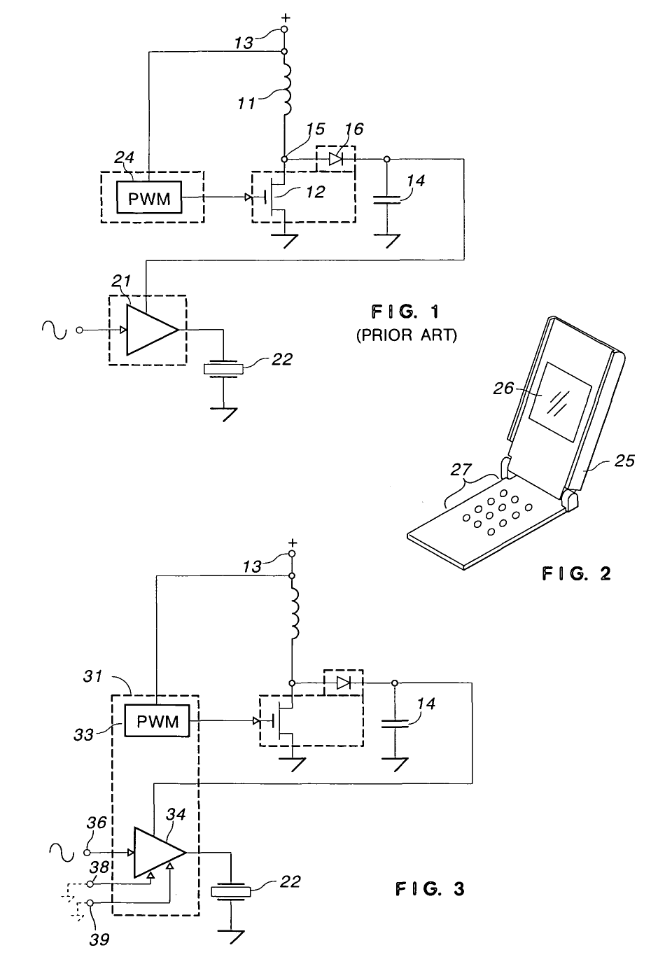

FIG. 2 illustrates electronic device 25 including display 26 and keypad 27. Either the display or the keypad, or both, can be provided with a piezoelectric device (not shown) for providing tactile feedback when a key or a portion of the display is depressed slightly. Devices for providing feedback are known in the art. As described above, such devices can be single layer or multi-layer and unidirectional or bidirectional.

FIG. 3 illustrates a driver for a piezoelectric actuator in which the circuitry for driving the gate of a switching transistor is on the same semiconductor die as the amplifier for controlling the device. Die 31 includes pulse width modulator 33 and amplifier 34, which is powered by high voltage from capacitor 14. By powering amplifier 34 from a high voltage supply, input 36 can receive voltages greater than external supply voltage 13, e.g. greater than three volts.

The output of amplifier 34 is coupled to piezoelectric actuator 22 for driving the device either unidirectionally or bidirectionally, depending upon input signal.

Although pulse width modulator 33 is a low voltage device and amplifier 34 is a high voltage device, the two are readily isolated on a die by techniques long known in the art for processing a semiconductor wafer.

In accordance with another aspect of the invention, die 31 includes at least two pads (not shown) coupled to inputs 38 and 29. These inputs are optionally grounded to provide at least four (2²) levels of gain in amplifier 34. If the invented driver is produced in large numbers, the pads can be grounded, or not, internally, thereby reducing pin count and package size. For small production runs, the pads can be coupled to external pins to allow a customer to set gain as desired.

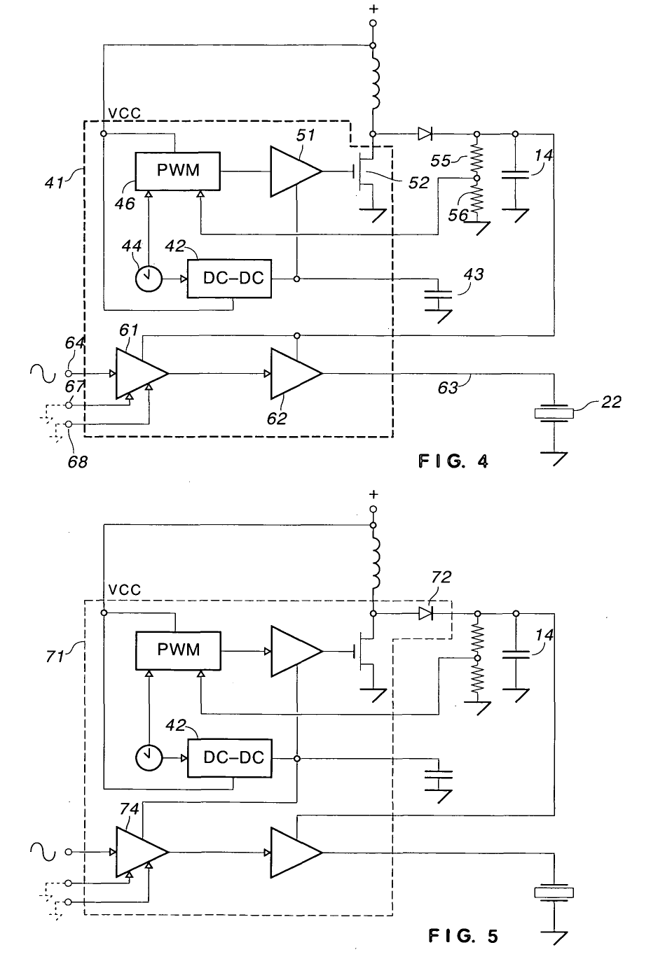

FIG. 4 is a block diagram of a preferred embodiment of the invention in which the switching transistor is included on the die with the pulse width modulator and the amplifier. In this embodiment, die 41 includes internal boost converter 42 for generating a local supply voltage on the die. Boost converter 42 is preferably a capacitive pump, known per se in the art, storing energy on external capacitor 43. The output from boost converter 42 is, for example, five volts, for powering buffer amplifier 51. By providing an internal supply voltage that is higher than V_{cc}, the battery voltage, one can drive the gate of switching transistor 52 at a higher voltage, thereby increasing the efficiency of the high voltage boost converter.

A voltage divider including resistor 55 and resistor 56 is coupled in parallel with capacitor 14 to provide feedback for controlling the voltage on capacitor 14.

Clock 44, which can include an oscillator and dividers or counters (not shown), is coupled to pulse width modulator 46 and boost converter 42, which need not operate at the same frequency.

A clock rate greater than 100 kHz. or higher is preferred for pulse width modulator 46. A clock rate in this range of frequencies enables one to use inductors that are physically small and less expensive. Current increases with inductance and decreases with frequency. The clock signal into boost converter 42 is preferably lower in frequency than the clock signal into pulse width modulator 46; e.g. one half or one fourth.

Input amplifier 61 and output amplifier 62 are powered by the supply voltage on capacitor 14. Output 63 of amplifier 62 is coupled to piezoelectric actuator 22. There can be more than two amplifying stages between input 64 and output 63. Amplifier 61 preferably includes at least two pads (not shown) coupled to inputs 67 and 68. As with the embodiment of FIG. 3, these inputs are optionally grounded to provide at least four levels of gain in amplifier 61.

FIG. 5 is a block diagram of an alternative embodiment of the invention that differs from the embodiment of FIG. 4 in two respects. Die 71 includes isolation diode 72 and amplifier 74 is powered by internal boost converter 42. Otherwise, the operation of the embodiment is the same as for FIG. 4.

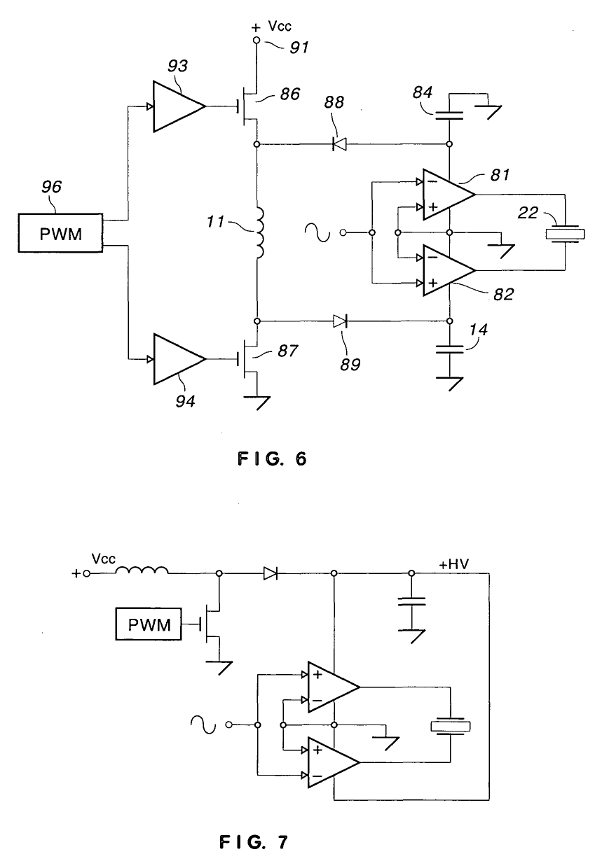

In FIG. 6, neither side of piezoelectric actuator 22 is grounded. Instead, the actuator “floats,” coupled between the output of amplifier 81 and the output of amplifier 82. Amplifier 82 is powered by capacitor 14, which is charged positively relative to ground. Amplifier 81 is powered by capacitor 84, which is charged negatively relative to ground. The absolute values of the voltages on capacitors 82 and 84 are much greater than the absolute value of V. Inductor 11, piezoelectric actuator 22, capacitor 85 and capacitor 85 are preferably the only components not included in a single semiconductor die.

The operation of the two polarity boost converter is very similar to that disclosed in U.S. Pat. No. 5,313,141 (Kimball). Briefly, while transistor 86 conducts, transistor 87 turns on and off, causing positive pulses to be coupled to capacitor 14. After a predetermined time, or number of pulses, the situation reverses and transistor 87 conducts while transistor 86 turns on and off, causing negative pulses to be coupled to capacitor 84. Diode 88 prevents current flowing from capacitor 84 to supply or ground. Diode 89 prevents current flowing from capacitor 14 to supply or ground.

The time constants associated with capacitors 14 and 84 are long enough that the voltage on the capacitors remains high, although fluctuating slightly because the voltage will decrease when a capacitor is not receiving charge pulses from the boost converter. The polarity of the boost pulses changes at a lower frequency than the pulse frequency of transistors 86 and 87. If the pulse frequency is greater than 500 kHz, for example, polarity can reverse at tens of kilohertz and the voltage on capacitors 14 and 84 is constant to within a few percent.

Aspects of the invention shown in other figures are omitted from FIG. 6 for the sake of simplicity, including the dashed line representing a single semiconductor die. This is not to say that the other aspects cannot be part of an implementation of the invention in accordance with FIG. 6. Techniques for biasing gate drive amplifiers 93 and 94 are not shown but are known in themselves in the art. Pulse width modulator 96 includes logic for driving the gates of transistors 86 and 87, in addition to generating a pulse width modulated signal.

The embodiment of FIG. 6 can drive the piezoelectric actuator over a range from +HV to −HV. FIG. 7 is a variation of this embodiment, using a single voltage supply. The embodiment of FIG. 7 can drive the piezoelectric actuator over a range from +HV to 0 (zero). This is one tradeoff. Another is that the embodiment of FIG. 6 requires dielectric isolation (DI) construction on a die, which is a more expensive process than the process needed to make the embodiment of FIG. 7.

The invention thus provides a single chip driver for a piezoelectric actuator that is as efficient as battery powered drivers using several semiconductor devices, thereby reducing the component count in drivers for piezoelectric actuators.

Having thus described the invention, it will be apparent to those of skill in the art that various modifications can be made within the scope of the invention. For example, the specific values given are by way of example only. One could enclose more than one semiconductor die in a single package. The pads for programming gain can be distributed among more than one amplifier in the embodiments of FIG. 4 and FIG. 5. Internal boost converter 42 (FIG. 4) can be added to die 31 (FIG. 3) also. More generally, while aspects of the invention have been described in certain combinations, this is not to imply that other combinations are not included in the invention. Although a two polarity boost converter, using a single inductor, is shown in FIG. 6, separate boost converters, using two inductors, could be used instead. Inductor 11 is illustrated as a simple coil but is intended to cover more complex alternatives as well, e.g. an autotransformer or a transformer with more than one winding.

What is claimed as the invention is:

1. A driver including a boost converter, a pulse width modulator controlling the boost converter, and an amplifier powered by the boost converter, characterized in that
the pulse width modulator and the amplifier are packaged as a single semiconductor device.

2. The driver as set forth in claim 1 wherein the pulse width modulator and the amplifier are formed on a single semiconductor die.

3. The driver as set forth in claim 2 wherein said die includes programming pads for adjusting the gain of said amplifier.

4. The driver as set forth in claim 2 and further including a second amplifier powered by the boost converter, wherein said driver has a complementary output.

5. The driver as set forth in claim 1 and further including a second amplifier and a second boost converter within said single semiconductor device, wherein said second boost converter supplies power to said second amplifier.

6. The driver as set forth in claim 5 wherein said boost converter includes a switching transistor and wherein said. second amplifier is coupled to a control electrode of said switching transistor.

7. In a battery operated, electronic device having a display and a keypad, at least one of which includes a piezoelectric actuator for tactile feedback, a driver coupled to said piezoelectric actuator and including a first boost converter, a pulse width modulator controlling the boost converter, and an output amplifier powered by the boost converter, characterized in that the driver further includes
a second amplifier coupling said pulse width modulator to said boost converter and a second boost converter for powering said second amplifier.

8. The electronic device as set forth in claim 7 and further including a second output amplifier powered by the boost converter, wherein said driver has a complementary output coupled to said piezoelectric actuator.

9. The electronic device as set forth in claim 7 wherein said output amplifier includes plural amplifying stages, at least one of which has programmable gain.

10. The electronic device as set forth in claim 9 wherein said output amplifier includes plural amplifying stages, at least one of which is powered by said second boost converter.

11. The electronic device as set forth in claim 7 wherein said first boost converter is inductive and the second boost converter is capacitive.

12. The electronic device as set forth in claim 7 wherein the output voltage of said first boost converter is greater than the output voltage of the second boost converter.

13. The electronic device as set forth in claim 7 wherein the absolute magnitudes of the output voltage of said first boost converter and the output voltage of the second boost converter are greater than the absolute magnitude of the battery voltage.

14. The electronic device as set forth in claim 7 wherein the pulse width modulator and the output amplifier are packaged as a single semiconductor device.

15. The electronic device as set forth in claim 7 wherein the pulse width modulator and the output amplifier are formed on a single semiconductor die.

16. The electronic device as set forth in claim 15 wherein said die includes programming pads for adjusting the gain of said amplifier.

17. The electronic device as set forth in claim 16 wherein said single semiconductor device includes programming pins coupled to said pads.

18. The electronic device as set forth in claim 7 and further including a second amplifier and a second boost converter within said single semiconductor device, wherein said second boost converter supplies power to said second amplifier.

19. The electronic device as set forth in claim 18 wherein said boost converter includes a switching transistor and wherein said second amplifier is coupled to a control electrode of said switching transistor.
